(19) United States
(12) Patent Application Publication
(10) Pub. No.: US 2012/0222737 A1
(43) Pub. Date: Sep. 6, 2012

(54) HOT CARRIER ENERGY CONVERSION STRUCTURE AND METHOD OF FABRICATING THE SAME

(75) Inventors: Gavin John Conibeer, Woronora Heights (AU); Santosh Shrestha, Seven Hills (AU); Dirk Konig, Maroubra (AU); Martin Andrew Green, Waverley (AU); Tomonori Nagashima, Gifu (JP); Yasuhiko Takeda, Nagakute Aichi (JP); Tadashi Ito, Nishikamo Aichi (JP); Tomoyoshi Motohiro, Seto Aichi (JP)

(73) Assignees: Toyota Jidosha Kabushiki Kaisha, Toyota-shi, Aichi-ken (JP); NewSouth Innovations Pty Limited, New South Wales (AU)

(21) Appl. No.: 13/378,580

(22) PCT Filed: Jul. 2, 2010
(86) PCT No.: PCT/AU2010/000848

§ 371 Date: May 18, 2012

(30) Foreign Application Priority Data
Jul. 3, 2009 (AU) 2009903121

(51) Int. Cl. H01L 31/02; H01L 31/18; B82Y 30/00; B82Y 99/00

(52) U.S. Cl. 136/256; 438/98; 257/E31.032; 257/E31.124; 977/774; 977/762; 977/755; 977/948

(57) ABSTRACT

A method of fabricating a hot carrier energy conversion structure, and a hot carrier energy conversion structure. The method comprises forming an energy selective contact ESC comprising a tunnelling layer; forming a carrier generation layer on the ESC; and forming a semiconductor contact without a tunnelling layer on the carrier generation layer.

### FIELD OF INVENTION

The present invention relates broadly to a hot carrier energy conversion structure, and to a method of fabricating the same.

### BACKGROUND

Solar cells that can convert the energy of sunlight directly into electric power have been attracting attention as a promising next generation dean energy source. To increase electric power generation per unit solar cell area, it is essential to increase photoelectric Conversion efficiency, and for this purpose, development of a device structure and device fabrication process, to improve the quality of Si as a principal material has been proceeding. Further, a multi junction solar cell has been developed that is constructed by combining three different kinds of materials (GaInP, GaInAs, and Ge) having absorption edges at different wavelengths. According to this structure, since light having a wide wavelength range contained in the sunlight can be absorbed, high conversion efficiency can be achieved. To further enhance the efficiency, multi junction solar cells constructed by combining four to six different kinds of materials are also being researched.

However, there is a limit to the degree to which the conversion efficiency can be enhanced by increasing the number of junctions. When the number of junctions is increased, the number of semiconductor interfaces having high defect density increases, and at such interfaces, carriers generated by the absorption of light are captured by the defects and are thus annihilated, as a result of which the photoelectric conversion efficiency drops. A further disadvantage is that the manufacturing cost greatly increases because of the use of many kinds of expensive III-V compound semiconductors and because of the complex multilayer structure requiring an increased number of fabrication steps.

On the other hand, solar cells have been proposed that employ device structures different from conventional ones, as means for enhancing the energy conversion efficiency (non-patent document 1). Among them, the “hot-carrier” theory is such that the carriers with a high energy state (hot carriers) generated by the absorption of light are allowed to move to the electrodes while maintaining the high energy state, thereby achieving high energy conversion efficiency. The solar cell to which the “hot-carrier” theory is applied has the advantage that light of a wide wavelength range contained in the sunlight can be absorbed for conversion into electric power while reducing energy losses, without having to increase the number of junctions (the number of kinds of the semiconductor materials used). In either case, when sunlight is incident into the carrier generation layer, carriers are generated that have various energies corresponding to the wavelengths of the incident light.

In the case of the conventional-type solar cell e.g. the high-energy electrons generated by the absorption of short-wavelength light reach an energy level corresponding to the bottom of the conduction band while causing thermal losses by the interactions with phonons; after that, the electrons pass through the electron transfer layer and are extracted from the electrode. As a result, the energy conversion efficiency of this device drops by an amount equal to the thermal losses. One possible method to reduce such thermal losses would be to raise the energy level at the bottom of the conduction band of the carrier generation layer, that is, to increase the bandgap Eg of the carrier generation layer.

The light at a longer wavelength, and having energy lower than the bandgap Eg of the carrier generation layer, is not absorbed in the carrier generation layer, but is lost as light transmission. As a result, if it is attempted to reduce the thermal losses of the high-energy carriers by increasing the bandgap Eg of the carrier generation layer, i.e., by raising the energy level at the bottom of the conduction band of the carrier generation layer, the number of carriers that cannot be excited into the conduction band will increase and, as a result, the loss due to light transmission will increase. Accordingly, in the conventional solar cell, it is not possible to use a material having too large a bandgap Eg. Further, since the carriers having an energy level corresponding to the bottom of the conduction band are extracted, the photovoltage of the conventional silicon solar cell is about 0.6 to 0.7 V, though it depends on the bandgap Eg and the quality of the carrier generation layer. Hence it is important to also not have too narrow a band gap or else the voltage is reduced.

In contrast to the conventional-type solar cell described above, in the hot-carrier-type solar cell energy selective contact (ESCs) are used. More particular, in the hot-carrier-type solar cell an electron transfer layer having a conduction band with a very narrow energy width and hole transfer layer having a balance band with a very narrow energy width are provided adjacent to the carrier generation layer, so that only the carriers having a specific energy can reach the electrodes by passing through the transfer layers. The carriers having a higher energy and the carriers having a lower energy undergo energy transfers between them, and after reaching the energy level that can pass through the transfer layers, these carriers pass through the transfer layers and reach the electrodes to contribute to power generation. As a result, thermal losses due to high-energy carriers decrease, and the energy conversion efficiency increases.

In order to reduce the loss due to light transmission, if the energy level at the bottom of the conduction band is lowered by using a narrow bandgap semiconductor material for the carrier generation layer, the generated low-energy carriers gain energy by interacting with high-energy carriers and, after reaching the energy level that can pass through the transfer layers, the carriers pass through the transfer layers and contribute to power generation. As a result, the loss due to light transmission decreases, and the energy conversion efficiency increases.

An alternative description of such a ESC, in thermodynamic terms, is that the carriers are thus collected with a very small increase in entropy. Ideally this collection would be isoentropic using mono-energetic contacts. It can be shown that the entropy generation is in the first order proportional to the energy width of the ESC and negligible as long as this width is much less than kT.

The extent to which the steady state current at the ESC energy is enhanced—as compared to the current that would result purely from absorption of photons giving initial carrier energies exactly at the ESC energy (zero renormalisation condition)—is determined by the efficiency and rate at which carrier energies renormalise and the comparison of this rate to the carrier extraction rate and to the thermalisation rate of carrier energies to the band edge.

The renormalisation rate in turn, will depend on the availability of carriers of equal energy difference both above and below the ESC energy—(this is first order renormalisation involving two carrier energies in one stage—second order renormalisation involves another stage and three or more carrier energies and will hence take longer). Thus renormalisation efficiency also depends on the position of the ESC energy with respect to the hot carrier population distribution. This introduces a small spectral sensitivity to the Hot Carrier cell, although it is thought that this is much smaller than the spectral sensitivity of a multiple tandem cell. However this spectral sensitivity does increase as the width of the ESC decreases.

Non-patent document 1 to 7 listed below describe various theoretical studies conducted on solar cells based on the “hot-carrier” theory.

[Non-patent document 1] “Potential for low dimensional structures in photovoltaics,” Green, Materials Science and Engineering B74(2000) 118-124.

[Non-patent document 2] “Solar energy conversion with hot electrons from impact ionisation,” Wurfel, Solar Energy Materials and Solar Cells 46(1997) 43-52.

[Non-patent document 3] “Selective Energy Contacts for Potential Application to Hot Carrier PV Cells,” Conibeer et al., 3rd World Conference on Photovoltaic Energy Conversion, May 11-18, 2003, 2730-2733.

[Non-patent document 4] “Third Generation Photovoltaics: Theoretical and Experimental Progress,” Green, 19th European Photovoltaic Solar Energy Conference, 7-11 Jun. 2004, 3-8.

[Non-patent document 5] “Particle Conversion in the Hot-Carrier Solar Cell,^{rt} Wurfel et al., Progress in Photovoltaics: Research and Applications, Prog. Photovolt: Res. Appl. 2005; 13:277-285.

[Non-patent document 6] “Phononic Band Gap Engineering for Hot Carrier Solar Cell Absorbers,” Conibeer et al., 20th European Photovoltaic Solar Energy Conference, 6-10 Jun. 2005, 35-38.

[Non-patent document 7] G. J. Conibeer, N. Ekins-Daukes, D. König, E-C. Cho, C-W. Jiang, S. Shrestha, M. A. Green, Solar Energy Materials and Solar Cells, 93 (2009) 713-719, “Progress on Hot Carrier solar cells”.

### SUMMARY

In accordance with a first aspect of the present invention there is provided a method of fabricating a hot carrier energy conversion structure, the method comprising forming an energy selective contact (ESC) comprising a tunnelling layer; forming a carrier generation layer on the ESC; and forming a semiconductor contact without a tunnelling layer on the carrier generation layer.

The ESC may comprise a negative ESC, and the semiconductor contact comprises a positive semiconductor contact.

The method may further comprise the step of controlling a work function of the semiconductor contact for controlling a work function difference between the ESC and the semiconductor contact.

The controlling the work function of the semiconductor contact may comprise selecting a material of the semiconductor contact, an oxide of the semiconductor contact, or both.

No high temperature annealing step is preferably required after the forming of the carrier generation layer.

The tunnelling layer may provide total energy filtering.

The semiconductor contact may be formed so that an energy level of a lower end of its conduction band is higher than the mean energy level of electrons or a peak energy level of an energy-density distribution of electrons generated in the carrier generation layer.

An energy level of a lower end of a conduction band of the semiconductor contact may be higher than an energy level of an upper end of an energy-density distribution of electrons generated in the carrier generation layer.

An energy level of a conduction band of the ESC may be substantially equal to a mean energy level of electrons or a peak energy level of an energy-density distribution of electrons generated in the carrier generation layer.

An energy level of an upper end of a valence band of the ESC may be lower than a means energy level of holes or a peak energy level of an energy-density distribution of holes generated in the carrier generation layer.

An energy level of an upper end of a valence band of the ESC may be lower than a lower end of an energy-density distribution of holes generated in the carrier generation layer.

The quantum effect layer may comprise an n-type semiconductor material buried in a barrier layer and an energy level of a conduction band of the electron transfer layer is chosen by controlling a dopant concentration of the n-type semiconductor material.

The barrier layer may comprise another n-type semiconductor material and an energy level of the barrier layer is chosen by controlling a dopant concentration of said other n-type semiconductor material.

The semiconductor contact may be formed so that an energy level of an upper end of its valence band is higher than an upper end of the valence band of the carrier generation layer.

The quantum effect layer may comprise one of a group consisting of a quantum well layer, quantum wires, and quantum dots.

The method may further comprise applying between the positive electrode and the negative electrode a voltage adjusted so as to maximize an output of the energy conversion device.

The applying the voltage may use a load whose resistance value has been adjusted so as to maximize said output.

In accordance with a second aspect of the present invention there is provided a hot carrier energy conversion structure comprising an energy selective contact ESC comprising a tunnelling layer; a carrier generation layer on the ESC; and a semiconductor contact without a tunnelling layer on the carrier generation layer.

The ESC may comprise a negative ESC, and the semiconductor contact comprises a positive semiconductor contact.

A work function of the semiconductor contact may be controlled for controlling a work function difference between the ESC and the semiconductor contact.

The controlling the work function of the semiconductor contact may comprise selecting a material of the semiconductor contact, an oxide of the semiconductor contact, or both.

The tunnelling layer may provide total energy filtering.

The semiconductor contact may have an energy level of a lower end of its conduction band higher than the mean energy level of electrons or a peak energy level of an energy-density distribution of electrons generated in the carrier generation layer.

An energy level of a lower end of a conduction band of the semiconductor contact may be higher than an energy level of an upper end of an energy-density distribution of electrons generated in the carrier generation layer.

An energy level of a conduction band of the ESC may be substantially equal to a mean energy level of electrons or a peak energy level of an energy-density distribution of electrons generated in the carrier generation layer.

An energy level of an upper end of a valence band of the ESC may be lower than a means energy level of holes or a peak energy level of an energy-density distribution of holes generated in the carrier generation layer.

An energy level of an upper end of a valence band of the ESC may be lower than a lower end of an energy-density distribution of holes generated in the carrier generation layer.

The quantum effect layer may comprise an n-type semiconductor material buried in a barrier layer and an energy level of a conduction band of the electron transfer layer is chosen by controlling a dopant concentration of the n-type semiconductor material.

The barrier layer may comprise another n-type semiconductor material and an energy level of the barrier layer is chosen by controlling a dopant concentration of said other n-type semiconductor material.

The semiconductor contact may have an energy level of an upper end of its valence band higher than an upper end of the valence band of the carrier generation layer.

The quantum effect layer may comprise one of a group consisting of a quantum well layer, quantum wires, and quantum dots.

The structure may further comprise means for applying between the positive electrode and the negative electrode a voltage adjusted so as to maximize an output of the energy conversion device.

The means for applying the voltage may be a load whose resistance value has been adjusted so as to maximize said output.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 is a diagram showing the basic structure of a hot-carrier type solar cell according to a first embodiment of the present invention.

FIG. 2(a) is a diagram showing the solar cell of FIG. 1 by orienting its layer stacking direction along the horizontal axis.

FIG. 2(b) is an energy band diagram for explaining the generation and movement of hot carriers in the solar cell of the structure shown in FIG. 1.

FIG. 3 is a diagram showing an electron energy-density distribution and a hole energy-density distribution in a carrier generation layer in the solar cell of FIG. 1.

FIG. 4 is a diagram showing the energy band structure of the solar cell of FIG. 1.

FIG. 5 is a diagram showing an electron energy-density distribution and a hole energy density distribution in a carrier generation layer in a solar cell according to a second embodiment of the present invention.

FIG. 6 is a diagram showing the energy band structure of a solar cell according to a third embodiment of the present invention.

FIG. 7(a) is a diagram showing the structure of a solar cell according to a fourth embodiment of the present invention.

FIG. 7(b) is an energy band diagram for explaining the generation and movement of hot carriers in the solar cell of the structure shown in FIG. 7(a).

FIG. 8 is a diagram showing an electron energy-density distribution and a hole energy-density distribution in a carrier generation layer in the solar cell of FIGS. 7(a) and 7(b).

FIG. 9 is a diagram showing an electron energy-density distribution and a hole energy-density distribution in a carrier generation layer in a solar cell according to a fifth embodiment of the present invention.

FIG. 10 is a diagram showing the energy band structure of a solar cell according to a sixth embodiment of the present invention.

FIG. 11 is a diagram showing the energy band structure of an eighth embodiment of the present invention.

FIG. 12 shows a flowchart illustrating a method of fabricating a hot carrier energy conversion structure according to an example embodiment.

### DETAILED DESCRIPTION

In the example embodiments described, application of an ESC is proposed for only the electron contact with a conventional p-type semiconductor for the hole collecting contact. This differs from the normal description of the Hot Carrier cell as having ESCs for both contacts. The inventors have recognised that a significant advantage of one ESC only is that a double carrier QD or QW structure (or other resonant tunnelling structure) need only be designed with one work function, rather than the two distinct ESC work functions that are required to give a voltage in a cell with two ESCs. In the example embodiments an appropriate work function difference can readily be obtained by tuning the doping of the p-type contact, a much easier process than tuning that of an ESC.

The inventors have further recognised that one ESC contact also has the significant advantage of greater manufacturability. With the ESC deposited first, a high temperature annealing step can be carried out before deposition of the absorber material, which is likely to be fragile. A two ESC device requires a high temperature phase after the deposition of the second ESC, and hence impacts on the absorber layer.

The inventors have further recognised that while such a one sided ESC device will not have quite the same limiting efficiency as a double ESC device, because most of the hot carrier energy in the absorber in practical applications is carried in the electron population (due to the smaller effective mass of electrons compared to holes in most materials), the loss of energy collected at the contacts due to a non-selective hole contact will be relatively small.

The inventors have further recognised that another important advantage of a one-sided ESC device is that it gives much more freedom in the choice of materials. For a double ESC device a work function difference must be established between the two contacts in order to establish an external voltage. This puts additional constraint on the material properties of the ESCs in that two different work functions have to be designed in addition to careful control of the quantum dot (QD) or quantum well (QW) size. In order to achieve this work function difference, doping of the QD/QW will be required for at least one ESC. Doping of such structures is not well understood but is likely to increase the defect density and hence reduce the effectiveness.

For a one sided ESC device in the example embodiments, the materials for the ESC advantageously only need to have the requisite quantum confinement—by control of QD/QW size—whereas the required difference in work function can be optimised in the other non-ESC contact which can be readily done by choosing an appropriate metal and potentially a suitable oxide to give a metal insulator semiconductor (MIS) type contact. Alternatively, a p-type semiconductor hole collecting contact may be used.

This separation of the requirements of the two contacts can advantageously greatly facilitate optimisation and is a direct result of the asymmetry generated by the one-sided ESC approach in the example embodiments. This advantageously provides higher achievable efficiencies in practice and a wider range of materials combinations, which hence reduces the chances of materials or process incompatibilities and will advantageously also enhance the ability to optimize the cost of materials and processes.

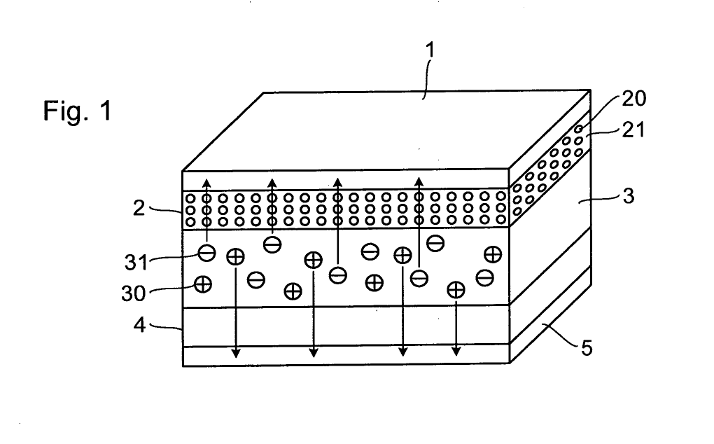

FIG. 1 is a diagram showing the structure of a hot-carrier type solar cell according to a first embodiment of the present invention. In the figure, reference numeral 1 is a negative electrode, and 2 is an electron transfer layer which contains a quantum effect layer 20 and a barrier layer 21. Reference number 4 is a p-semiconductor contact without a tunnelling layer and reference numeral 5 is a positive electrode.

The negative electrode 1 is connected to the electron transfer layer 2, and acts to collect the electrons generated in the carrier generation layer 3. The electrons pass through the electron transfer layer 2. The negative electrode 1 is formed from a transparent conductive layer, which may be coated with an anti-reflective film formed by combining a high-refractive index film and a low-refractive index film. The negative electrode 1 may be constructed, for example, from a comb-shaped electrode, as in the case of a conventional solar cell. The electron transfer layer 2 contains the quantum effect layer 20 within the barrier layer 21 so as to exhibit a carrier confinement effect (quantum effect). The quantum effect layer 20 is formed, for example, from a quantum well layer, quantum wires, or quantum dots. In the electron transfer layer 2, the energy width of the conduction band where carriers can exist is narrow due to the carrier confinement effect of the quantum effect layer 20. In one example, the bandgap of the barrier layer 21 is 4.0 to 5.0 eV, and the thickness is 2 to 10 nm; when the quantum effect layer 20 is formed from quantum dots, the dot diameter (φ) is 2 to 5 nm, and the bandgap is 1.8 to 2.2 eV.

The carrier generation layer 3 is formed from an n-type, i-type, or p-type semiconductor material, such as Si, C, or a III-V compound semiconductor, and generates positive and negative carriers having energies corresponding to the wavelengths of sunlight by absorbing the sunlight. Holes 30 as positive carriers are collected by the positive electrode 5. Electrons 31 as negative carriers are passed through the electron transfer layer 2 and reach the negative electrode 1 where the electrons are collected. In one example, the carrier generation layer 3 is formed principally from a material whose bandgap is 0.5 to 1.0 eV.

The positive electrode 5 collects the holes generated in the carrier generation layer 3. The positive electrode 5 is formed, for example, from a metal such as aluminium. In the embodiment shown in FIG. 1, the negative electrode 1 is provided on the light receiving side, using e.g. a thin metal contact or a transparent conducting oxide, and the structure formed on a substrate (not shown) in a bottom-up fabrication process. Alternatively, the positive electrode 5 may be provided on the light receiving side. In that case, the structure can be fabricated on a transparent superstrate in the same order, with the metal contact, which can then be opaque, being disposed on the back of the structure in a use orientation with the superstrate on the light receiving side. Further, the carrier generation layer 3 may be formed from a material that generates electrons and holes by absorption of thermal energy, rather than from a material that generates electrons and holes by absorption of light.

It is noted that the collection of carriers at higher energies from the absorber layer will typically be quite small in normal semiconductors because carrier thermalisation with phonons is efficient and reduces the population of hot carriers within a few pico-seconds. This reduces the hot electrons available to scatter with cold electrons in electron-electron renormalisation scattering events—even though these events are very fast (10 s femto-seconds), and thus reduces the re-population of the depleted energy level of the energy selective contact.

Nonetheless normal semiconductors can be used to demonstrate the hot carrier effect in one sided ESC devices of example embodiments. Collection with these materials as the ‘absorber layer’ will be from close to the interface with the energy selective contact (e.g. about 10-20 nm). This is the region from which hot carriers will be able to diffuse in a few pico-seconds, i.e. before they can thermalise. A high illumination intensity can further enhance the hot carrier effect through the build up of emitted phonons which can inhibit further cooling.

Some existing bulk semiconductors can enhance this ‘phonon bottleneck effect’ through their restricted availability of allowed phonon modes, which can limit the decay of high energy localised optical phonons to low energy travelling acoustic phonons (i.e. heat). Suitable materials preferably have a large difference between the masses of their constituent atoms and are thus compounds. An example material is InN. The large disparity in mass results in separate and fairly discrete energies for optical and acoustic phonon modes with a large gap between the two dispersions which can inhibits the optical to acoustic phonon decay.

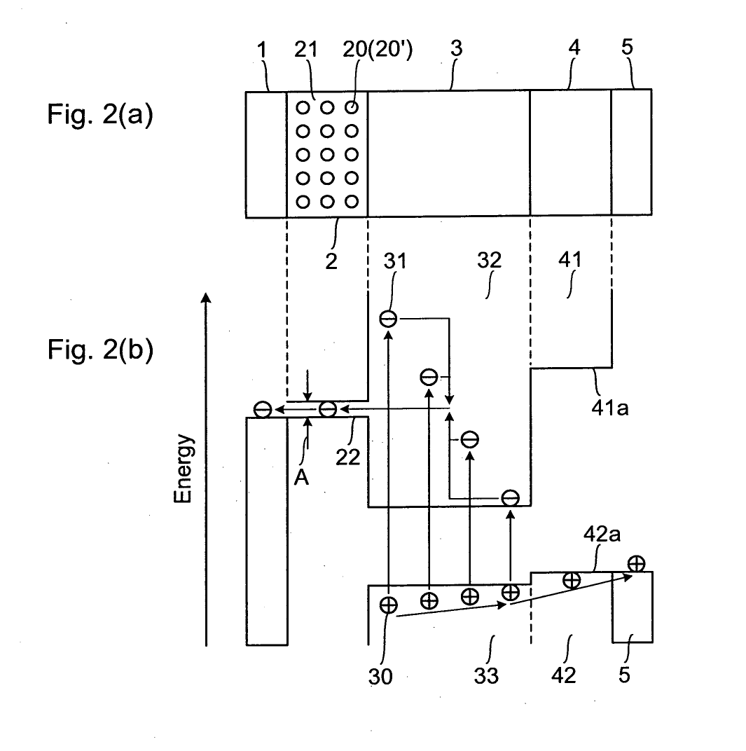

FIG. 2 is a diagram showing the power generation principle of the hot-carrier type solar cell shown in FIG. 1; the diagram here specifically shows the generation and movement of hot carriers in the carrier generation layer 3. Part (a) of FIG. 2 shows the solar cell by orienting, its layer stacking direction along the horizontal axis, and part (b) shows the energy band structure in each layer.

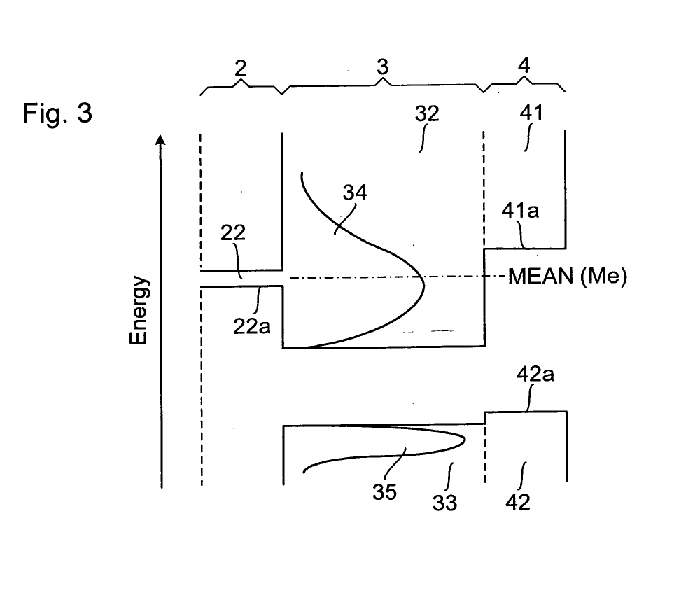

Electrons and holes generated in the carrier generation layer 3 by absorption of light are excited to the energy levels corresponding to the wavelengths of the incident light. That is, in the conduction band 32, electrons 31 with high energies are generated for the short wavelengths of light, and electrons 31 with low energies for the long wavelengths of light, while in the valence band 33, holes 30 with high energies are generated for the short wavelengths of light, and holes 30 with low energies for the long wavelengths of light. In the conduction band 32, energy transfers occur due to the interactions between the high-energy and low-energy electrons, and the electron energy-density distribution (see, for example, FIG. 3) thus reaches thermal equilibrium.

In the electron transfer layer 2, the energy widths of the conduction band is narrow due to the carrier confinement effect of the quantum wells, quantum wires, quantum dots, or the like. This results in the formation of a conduction band 22 having a restricted energy width (energy width A) in the electron transfer layer 2, and these are connected to the carrier generation layer 3. As a result, in the electron energy-density distribution in the carrier generation layer 3, only the electrons having specific energy levels are allowed to move to the negative electrode 1. On the other hand, holes 30 generated in the carrier generation layer 3 move to the positive electrode 5 via the valence band 42 of the p-semiconductor contact 4.

FIG. 3 is a diagram showing the characteristics of the solar cell according to the present embodiment, in particularly, the relationships between the electron energy-density distribution in the carrier generation layer 3 and the energy levels of the electron transfer layer 2. In the figure, the ordinate represents the energy levels. In FIG. 3, reference numeral 34 indicates the electron energy-density distribution in the carrier generation layer 3. As earlier described, when light is absorbed in the carrier generation layer 3, electrons and holes excited to the energy levels corresponding to the absorbed wavelengths are generated in the conduction band 32, and after that, interactions involving energy transfers occur between the electrons resulting in the formation of the electron energy-density distribution 34 as shown in FIG. 3.

In the solar cell of the present embodiment, the energy level 22a at the bottom of the conduction band 22 in the electron transfer layer 2 is set dose to or approximately equal to the mean energy level of the electrons generated in the carrier generation layer 3. On the other hand, the energy level 41 a of a lower end of the conduction band 41 of the semiconductor contact 4 is higher than the mean energy of the electrons generated in the carrier generation layer 3.

In the solar cell of the present embodiment, since the energy level 22a at the bottom of the conduction band 22 in the electron transfer layer 2 is set dose to the mean energy of the electrons generated in the carrier generation layer 3, as shown in FIG. 3, only the electrons having energies at or near the mean energy level are allowed to move to the negative electrode 1. This serves to reduce the thermal loss of the electrons and enhance the energy conversion efficiency.

If the energy level 22a at the bottom of the conduction band in the electron transfer layer 2 is set higher than the mean energy of the electrons, since the high-energy electrons generated in the carrier generation layer 3 are allowed to move to the negative electrode 1, the density of the high-energy electrons that give up energy to the low-energy electrons decreases. As a result, the density of the electrons that become lower than the energy level 22a at the bottom of the conduction band in the electron transfer layer 2 increases in the carrier generation layer 3, and hence, the density of the electrons being unable to move to the negative electrode 1 increases, thus increasing the energy loss. Conversely, if the energy level 22a at the bottom of the conduction band is set lower than the mean energy of the electrons, since the low-energy electrons are allowed to move to the negative electrode 1, the energy loss of the high-energy electrons increases. Furthermore, since the energy level 22a at the bottom of the conduction band is lowered, the photovoltage of the solar cell decreases.

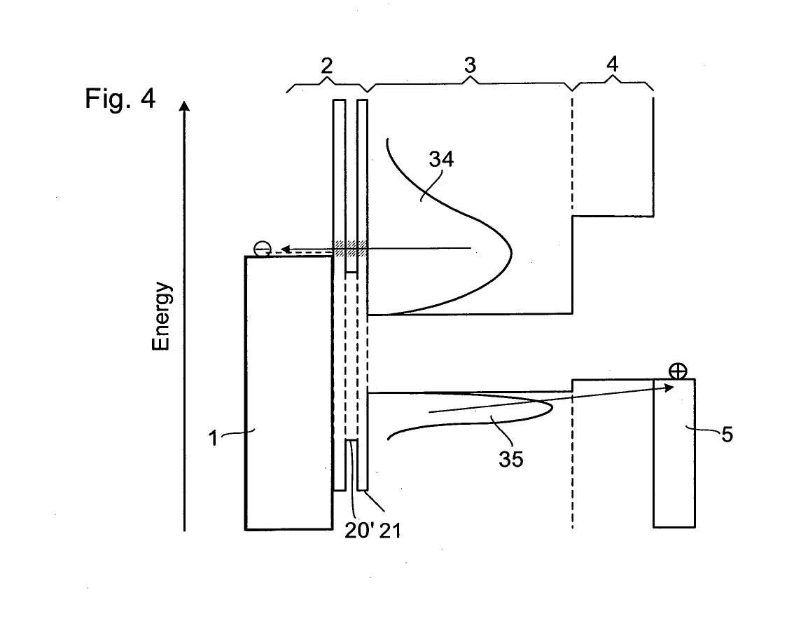

FIG. 4 shows one example of the energy band structure of the above-described hot-carrier type solar cell. In the structure of FIG. 4, a material whose bandgap is 4.0 to 5.0 eV is selected for the barrier layer 21 of the electron transfer layer 2, and the thickness is 2 to 10 nm. On the other hand, a material whose bandgap is 1.8 to 2.2 eV is selected for the quantum dots 20′, and the dot diameter (φ) is 2 to 5 nm. The carrier generation layer 3 is formed principally from a material whose bandgap is 0.5 to 1.0 eV. The p-semiconductor contact 4 is formed principally from a material whose bandgap is 1.8 to 3 eV with a work function that preferably lines up with the valence band of the carrier generation layer.

Because of the interactions between the energies of the electrons in the conduction band the energy loss due to the electrons that are excited to have higher energies, the thermal loss in the conventional type solar cell, can be reduced. Even when the bandgap is reduced, the energy loss of the electrons does not increase. As a result, a narrow-gap semiconductor material can be used for the carrier generation layer, which serves to reduce the loss due to light transmission. Furthermore, with the simple structure shown in FIG. 1, light of a wide wavelength range contained in the sunlight can be converted into electrical energy while minimizing the energy losses, as efficiently as with a multi-junction solar cell having five or more junctions. Accordingly, a solar cell having high energy conversion efficiency and inexpensive to manufacture can be achieved.

In the present embodiment, the electron transfer layer 2 comprises a double barrier resonant tunnelling layer for the selective energy contact, with quantum dots providing a discrete energy level between two insulating barriers. This can give conduction strongly peaked at the discrete energy level. The total energy filtering of a quantum dot based structure is preferred for a selective energy contact rather than 1D energy filtering because the 1D energy filtering in, for instance, a quantum well resonant tunnelling device is only effective for carriers with momenta entirely perpendicular to the plane of the well. Carriers with components of momenta away from this normal can be transmitted if the vector sum of their energy and momentum (the total energy) is within the energy range of the energy filter, even though their static energy (independent of momentum) is outside this range. This leads to a broadening of the range of carrier energies transmitted by a 1D filter and significantly reduces its efficiency. Hence in the present embodiment resonant tunnelling structures using quantum dots or other discrete total energy confined centres as the resonant centres are used advantageously giving the total energy filtering. Such a filter should exhibit negative differential resistance (NDR) in all directions.

The fabrication of double barrier resonant tunnelling structures consisting of silicon quantum dots (Si QDs) in silicon dioxide (SiQ₂) matrix has been demonstrated e.g. in the ARC Photovoltaics Centre of Excellence, UNSW [E.-C. Cho, Y. H. Cho, R. Corkish, J. Xia, M. A. Green, D. S. Moon, Asia-Pacific Nanotechnology Forum, Cairns, 2003; E.-C. Cho, Y. H. Cho, T. Trupke, R. Corkish, G. Canibeer, M. A. Green, Proc. 19th European Photovoltaic Solar Energy Conference, Paris, 2004]. In the present embodiment, alternate layers of SiO₂, Silicon-rich oxide (SiOₓ₂, x<2) and SiO₂ of desired thicknesses are deposited by RF magnetron sputtering. The layers are grown by co-sputtering from Si and quartz targets. Silicon-rich oxide (SRO) is thermodynamically unstable below 1173° C. and phase separation in the SiO₂ film results in precipitation of Si nanocrystals which form quantum dots (QDs).

The size of Si QDs can be controlled by adjusting the initial SRO layer thickness and the crystallization conditions. The diameter of the nanocrystals is substantially equal to the SRO thickness for film thicknesses less than 10 nm, giving uniform size controllability. The spatial density of Si QDs can be controlled by the stoichiometry of the SRO film. Si QD structures have shown negative differential resistance at room temperature, characteristic of resonant tunnelling.

It is noted, however, that in alternative embodiments a quantum well can also be used although this will only provide energy filtering in 1D unlike e.g. quantum dots providing total energy filtering.

In the present embodiment, the quantum effect structure consists of 5 nm barriers of sputtered SiO₂ between which was sputtered a 4 nm layer of Si rich silicon oxide. On annealing at e.g. about 1100° C., Si nanocrystals precipitate from the Si rich layer, limited in size to the thickness of the layer, as determined by transmission electron microscopy (TEM). The small size of these nanocrystals is such that discrete quantum confined energy levels develop (as suggested by photoluminescence for other samples) such that they can be regarded as true quantum dots. Mesas of area 1/16 cm² were prepared lithographically. For the growth and anneal conditions used in the present embodiment, each mesa of this size contains about 10¹⁰ Si QDs.

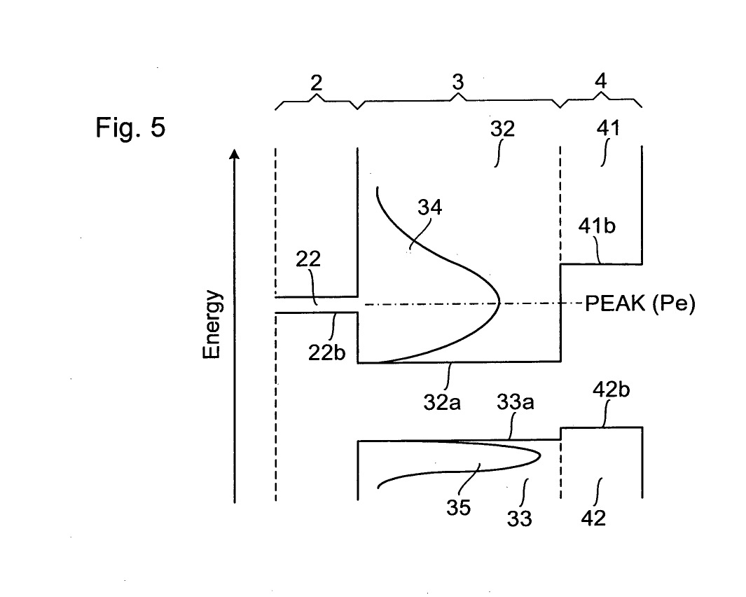

FIG. 5 shows the characteristics of a solar cell according to a second embodiment of the present invention. The solar cell of this embodiment has the same multi layer structure as that of the solar cell shown in FIG. 1, but the energy level 22b at the bottom of the conduction band in the electron transfer layer 2 is set close to or approximately equal to the peak value Pe of the electron energy-density distribution 34 in the carrier generation layer 3. Further, the energy level 41b of the lower end of the conduction band 41 of the p-semiconductor contact 4 is set higher than the peak energy level of the energy-density distribution of the electrons generated in the carrier generation layer 3.

When the energy level 22b at the bottom of the conduction band 22 in the electron transfer layer 2 is set dose to the peak energy level of the energy-density distribution of the electrons generated in the carrier generation layer 3, the interactions between the high-energy and low-energy electrons can be promoted, reducing the energy loss as a whole. As a result, the current density increases, and the photoelectric conversion efficiency improves. On the other hand, the higher end 42b of the valence band 42 of the p-semiconductor contact 4 is set higher than the upper end 33a of the valence band of the carrier generation layer 3.

In one example, in the structure shown in FIG. 5, the peak energy level Pe of the electron energy-density distribution 34 is set higher by 0.3 to 1.0 eV than the energy level 32a at the bottom of the conduction band of the carrier generation layer 3. Further, the energy level 22b at the bottom of the conduction band 22 in the electron transfer layer 2 is set so as to lie within a range of ±0.1 eV with respect to the peak energy level Pe of the electron energy-density distribution in the carrier generation layer 3.

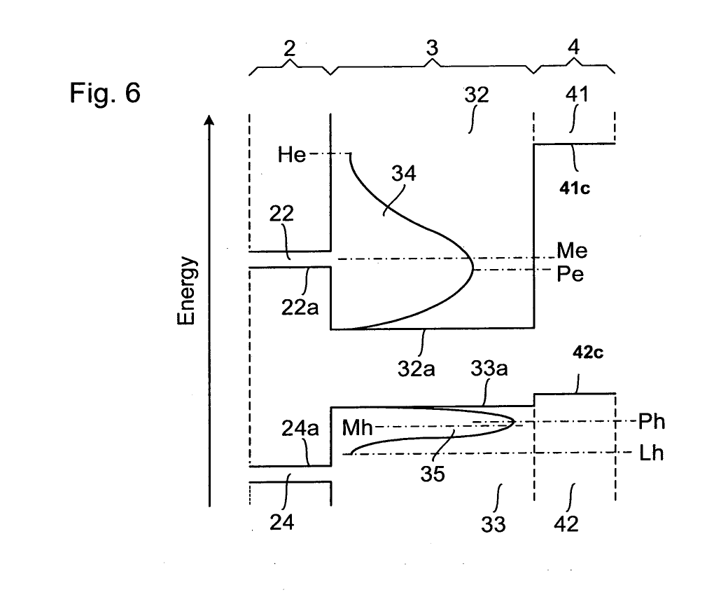

FIG. 6 shows the energy band structure of a hot-carrier type solar cell according to a third embodiment of the present invention. In the foregoing first and second embodiments, attention has been paid to the energy level at the bottom of the conduction band in the electron transfer layer, but in the present embodiment, attention is also paid to the energy level at the top of the valence band in the electron transfer layer, thereby proposing a solar cell having higher energy conversion efficiency.

As shown in FIG. 6, in the solar cell of the present embodiment, the energy level 24a at the top of the valence band 24 in the electron transfer layer 2 is set lower than the mean energy level Mh of the hole energy-density distribution 35 in the carrier generation layer 3 or than the peak energy level Ph of the hole energy-density distribution 35. With this structure, the holes generated in the carrier generation layer 3 can be prevented from moving into the electron transfer layer 2 and being annihilated by recombining with the electrons existing in the electron transfer layer 2. In other words, the current loss associated with the annihilation of the generated carries decreases, and the photoelectric conversion efficiency further improves. On the other hand, the lower end 41c of a conduction band 41 of the p-semiconductor contact 4 is set higher than energy level He of an upper end of the energy-density distribution 34 of electrons in the carrier generation layer 3, thus preventing electrons generated in the carrier generation layer 3 from moving into the p-semiconductor contact 4.

In one example of the present embodiment, the mean energy level Me or the peak energy level Pe of the electron energy-density distribution 34 in the carrier generation layer 3 is set higher by 0.3 to 1.0 eV than the energy level 32a at the bottom of the conduction band 32 in the carrier generation layer 3. Further, the energy level 24a at the top of the valence band in the electron transfer layer 2 is set so as to lie within a range of −0.8 eV to 0 eV with respect to the mean energy level Mh or the peak energy level Ph of the hole energy-density distribution 35. As a result, the current density of the solar cell increases, and the photoelectric conversion efficiency further improves.

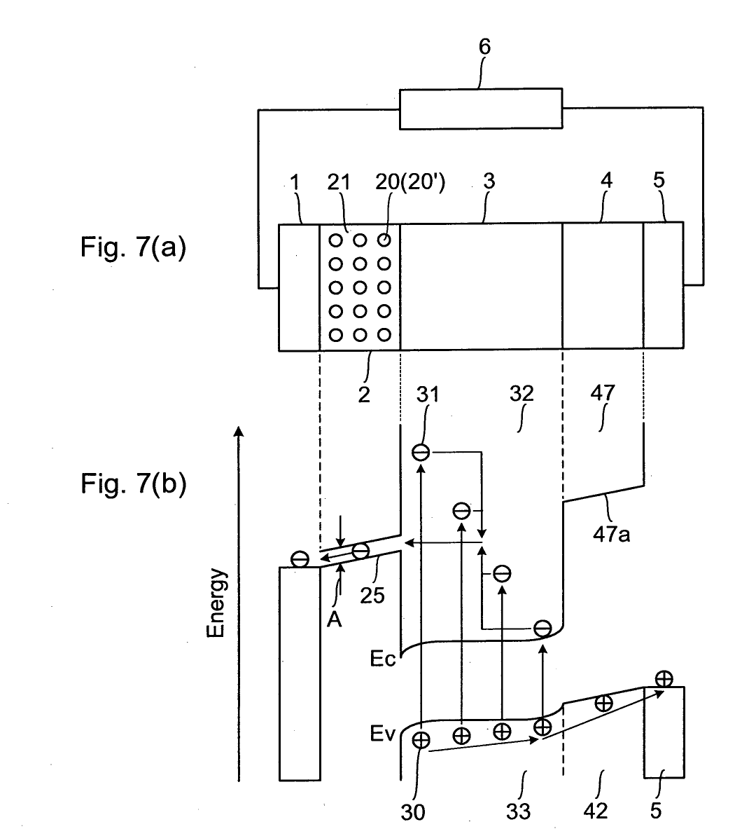

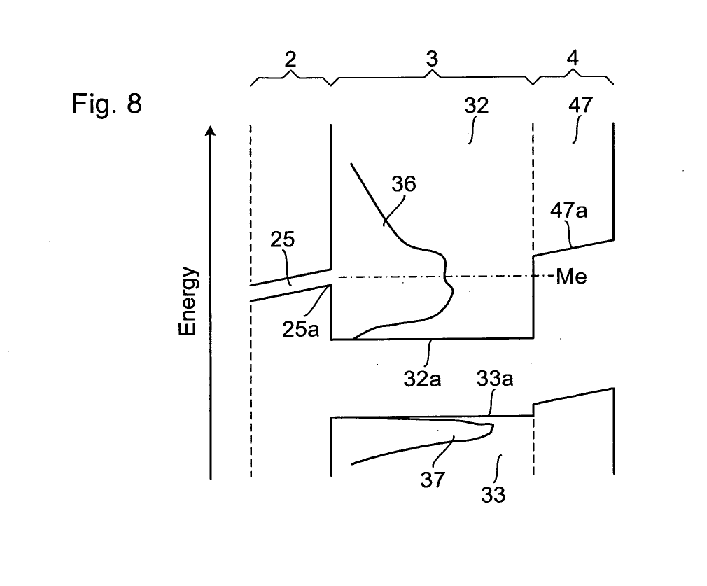

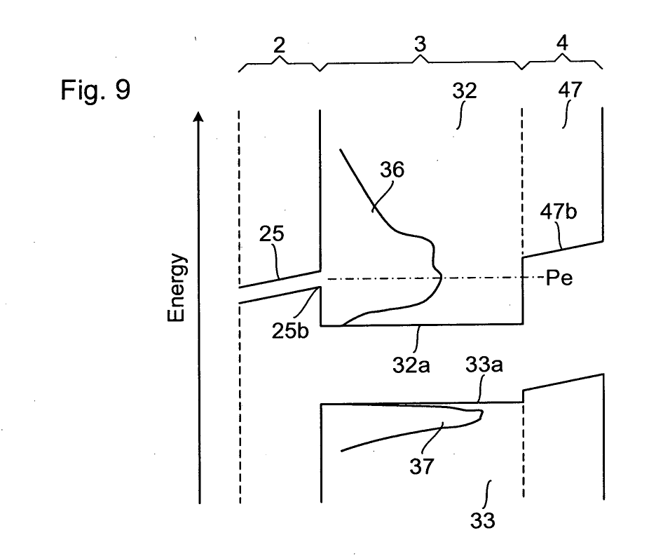

FIG. 7(a) shows the structure of a solar cell according to a fourth embodiment of the present invention, and FIG. 7(b) schematically shows the generation and movement of carriers in the solar cell shown in FIG. 7(a). In FIGS. 7(a) and 7(b), the same reference numerals as those in FIGS. 1 and 2 designate the same or similar component elements, and the description thereof will not be repeated here. When supplying power outside the solar cell, the solar cell is connected to a load 6, and a voltage adjusted so as to maximize the output is applied between the electrodes. Or the resistance value of the load 6 is adjusted so as to maximize the output. As a result, a current flow through the solar cell, that is, the carriers (electrons and holes) move through the device, and thus the energy levels of the negative electrode 1, the electron transfer layer 2, the carrier generation layer 3, and the positive electrode 5 change. For example, the energy level of the electron transfer layer 2 becomes lower than that shown in FIG. 2. Likewise, the electron energy and whole energy-density distributions in the carrier generation layer 3 also change as shown in FIGS. 8 and 9.

The energy level at the bottom of the conduction band in the electron transfer layer 2 in the first embodiment shown in FIG. 2 corresponds to the energy levels in the open-circuit condition. However, in the condition in which the load 6 is connected and a current flow through the device, since the energy levels of the respective regions change as described above, the energy level at the bottom of the conduction band in the electron transfer layer 2 optimized for the steady-state condition are not necessarily optimum.

In the present embodiment, in the condition in which the load 6 is connected to the solar cell, as shown in FIG. 7, and a voltage adjusted so as to maximize the output is applied between the negative electrode 1 and the positive electrode 5, or the resistance value of the load 6 is adjusted so as to maximize the output, the energy level 25a at the bottom of the conduction band 25 in the electron transfer layer 2 is set dose to the mean value of the electron energy-density distribution 36 formed in the carrier generation layer 3, as shown in FIG. 8. As a result, the energy loss of the carriers decreases, and the conversion efficiency improves. On the other hand, the lower end 47a of the conduction band 47 of the p-semiconductor contact 4 is set higher than the mean value of the electron energy-density distribution 36 formed in the carrier generation layer 3.

In one example, the mean energy level of the electron energy-density distribution 36 in the carrier generation layer 3 is set higher by 0.3 to 1.0 eV than the bottom 32a of the conduction band in the carrier generation layer 3. The energy level 25a at the bottom of the conduction band in the electron transfer layer 2 is set so as to lie within a range of +0.1 eV with respect to the mean energy level of the electron energy-density distribution 36 in the conduction band in the carrier generation layer 3.

With this structure, a solar cell having improved energy conversion efficiency can be achieved.

FIG. 9 shows the electron energy and hole energy-density distributions in the carrier generation layer in a solar cell according to a fifth embodiment of the present invention. The solar cell of the present embodiment has the same basic structure as that shown in FIG. 7(a), but the difference is that, in the condition in which the load 6 is connected to the solar cell, and a voltage adjusted so as to maximize the output is applied between the negative electrode 1 and the positive electrode 5, or the resistance value of the load 6 is adjusted so as to maximize the output, the energy level 25b at the bottom of the conduction band 25 in the electron transfer layer 2 is set close to the peak energy level of the electron energy-density distribution 36 in the conduction band 32 of the carrier generation layer 3, thereby increasing the current density of the solar cell and enhancing the energy conversion efficiency. On the other hand, the energy level 47b of the lower end of the conduction band 47 of the p-semiconductor contact 4 is set higher than the peak energy level of the electron energy-density distribution 36 in the conduction band 32.

In one example, the peak energy level of the electron energy-density distribution 36 in the carrier generation layer 3 is set higher by 0.3 to 1.0 eV than the bottom 32a of the conduction band in the carrier generation layer 3. The energy level 25b at the bottom of the conduction band 25 in the electron transfer layer 2 is set so as to lie within a range of ±0.1 eV with respect to the peak energy level of the electron energy-density distribution 36 in the conduction band 32 of the carrier generation layer 3.

With this structure, a solar cell having improved energy conversion efficiency can be achieved.

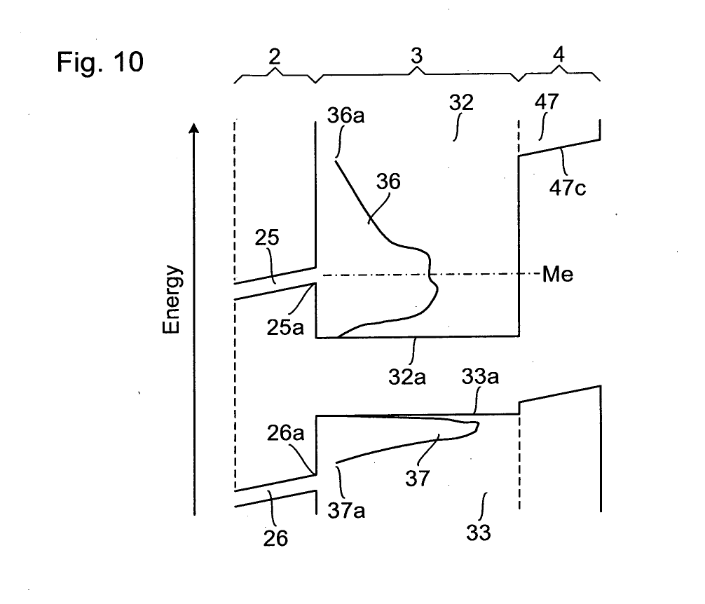

FIG. 10 shows the energy band, structure of a solar cell according to a sixth embodiment of the present invention. The basic structure and the hot-carrier generation and movement principles of the solar cell of this embodiment are the same as those shown in FIG. 7. However, in the present embodiment, the energy level 26a at the top of the valence band 26 in the electron transfer layer 2 Is set lower than the mean energy level or peak energy level of the hole energy-density distribution 37 formed in the carrier generation layer 3. Or, preferably, it is set lower than the bottom 37a of the whole energy-density distribution 37. On the other hand, the energy level 25a at the bottom of the conduction band 25 in the electron transfer layer 2 is set in the same manner as in the fourth and fifth embodiments shown in FIGS. 8 and 9. The energy level 47c of the lower end of the conduction band 47 of the p-semiconductor contact 4 is set higher than the energy level 36a of an upper end of the electron energy-density distribution 35.

With the above structure, the current density of the solar cell can be increased and the energy conversion efficiency enhanced.

In one example, the peak energy level of the electron energy-density distribution 36 in the carrier generation layer 3 is set higher by 0.3 to 1.0 eV than the energy level 32a at the bottom of the conduction band of the carrier generation layer 3. The energy level 26a at the top of the valence band in the electron transfer layer 2 is set so as to lie within a range of −0.8 eV to 0 eV with respect to the mean or peak energy level of the hole energy-density distribution 37 in the carrier generation layer 3.

With this structure, a solar cell having improved energy conversion efficiency can be achieved.

A seventh embodiment concerns controlling the energy levels of the conduction band and the valence band in the electron transfer layer 2 in the solar cell according to any one of the above-described first to sixth embodiments. The energy levels of the conduction band and the valence band in the electron transfer layer formed, for example, by the quantum wells, quantum wires, or quantum dots that form the quantum effect layer. Accordingly, the present embodiment proposes that the energy level at the bottom of the conduction band of the electron transfer layer be set close to the mean or peak energy level of the electron energy-density distribution in the conduction band of the carrier generation layer 3, and that the energy level at the top of the valence band be set lower than the mean or peak energy level of the hole energy-density distribution.

To achieve the above structure, in the present embodiment the quantum effect layer (quantum well layer, quantum wires, or quantum dots) 20 in the electron transfer layer 2 shown, for example, in FIG. 3(a) or FIG. 7(a), is formed from an n-type semiconductor material, with provisions made to adjust the energy level of each quantum effect layer to the desired value by controlling the dopant concentration in the semiconductor material.

If semiconductor materials whose dopant concentrations are not controlled are used, it becomes difficult to reduce the current loss because, when the energy level at the bottom of the conduction band is set to the optimum level, for example, the energy level at the top of the valence band becomes higher than the optimum level. Conversely, when the energy level at the top of the valence band is set to the optimum level, the energy level at the bottom of the conduction band becomes higher than the optimum level, and the current loss increases. In view of this, in the present embodiment, the electron transfer layer is formed from an n-type semiconductor, and the energy levels of the conduction band and the valence band are both optimized by adjusting the dopant element concentration. By optimizing these energy levels, the current density increases, and the conversion efficiency improves.

In one example, the quantum dots 20′ in the electron transfer layer 2 are formed from an n-type semiconductor whose bandgap is 2.0 to 2.5 eV and whose carrier density is 10¹² to 10¹⁸ cm³.

An eight embodiment concerns controlling the energy levels of the barrier layer in the electron transfer layer 2 in the solar cell of the above-described seventh embodiment. An insulating material or a semiconductor material with a large bandgap can be used for forming the barrier layer 21 in the electron transfer layer 2. For the electrons to move from the carrier generation layer 3 to the negative electrode, the loss caused by resistance, etc. during the movement is preferably reduced. For this purpose, in the electron transfer layer 2, the difference between the energy level at the bottom of the conduction band in the quantum effect layer 20 and that at the bottom of the conduction band in the barrier layer 21 are preferably reduced.

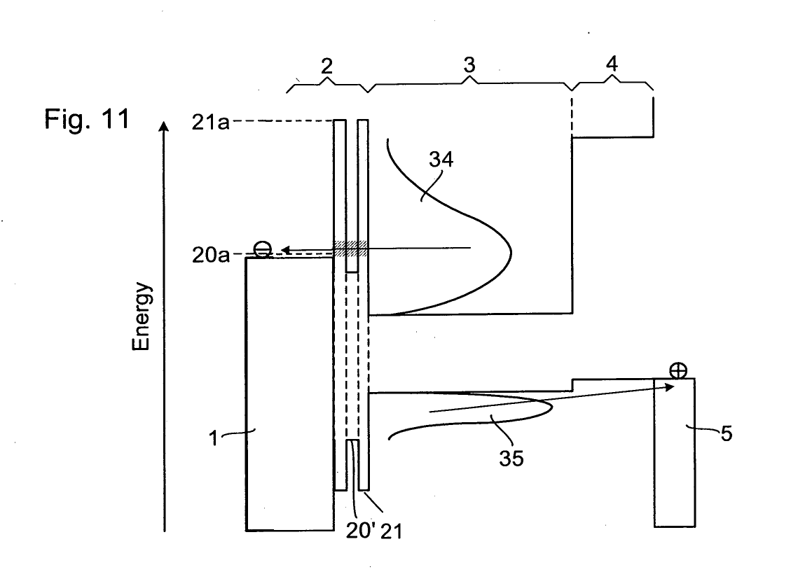

FIG. 11 shows the energy band structure of the solar cell in which the energy level difference between the quantum effect layer and the barrier layer is reduced. As shown, in the electron transfer layer 2, the difference between the energy level 21a at the bottom of the conduction band in the barrier layer 21 and the energy level 20a at the bottom of the conduction band in the quantum dots 20′ is preferably reduced.

Accordingly, when the quantum effect layer is formed by controlling its dopant concentration as shown in the seventh embodiment, the energy level difference can be reduced by also controlling the dopant concentration in the barrier layer. This serves to reduce the resistance loss of the solar cell and enhance the energy conversion efficiency. For this purpose, in the present embodiment, the barrier layer 21 in the electron transfer layer is formed from an n-type semiconductor material.

In one example, the barrier layer 21 in the electron transfer layer 2 is formed from an n-type semiconductor material whose bandgap is 3.5 to 4.5 eV and whose carrier density is 10¹² to 10¹⁸ cm⁻³.

A ninth embodiment studies the energy width A (see FIGS. 2(a) and 7(a)) of the conduction band in the electron transfer layer 2. In the energy conversion device of the present embodiment, of the carriers generated in the carrier generation layer 3, only the electrons and holes having energy levels near the mean or peak value are allowed to move to the negative electrode, respectively, thus reducing the energy loss of the carriers.

If the energy width A is large, since electrons having energies higher than the mean or peak energy of the electron energy-density distribution move to the negative electrode, the energy loss increases. If the high-energy electrons are allowed to move to the negative electrode, the density of the high-energy electrons that give up energy to the low-energy electrons decreases. As a result, the density of the electrons having energies lower than the conduction band energy level of the electron transfer layer increases, and hence, the density of the electrons being unable to move to the electrode increases, thus increasing the energy loss. On the other hand, if the low-energy electrons are allowed to move to the negative electrode, the energy loss of the high-energy electrons increases. Further, the photovoltage decreases.

Accordingly, in the present embodiment, the energy width A of the conduction band in the electron transfer layer is set to 0.2 eV or less, and preferably to 0.05 eV or less. With this structure, the energy loss of the electrons decreases, and a solar cell having high energy conversion efficiency can be achieved.

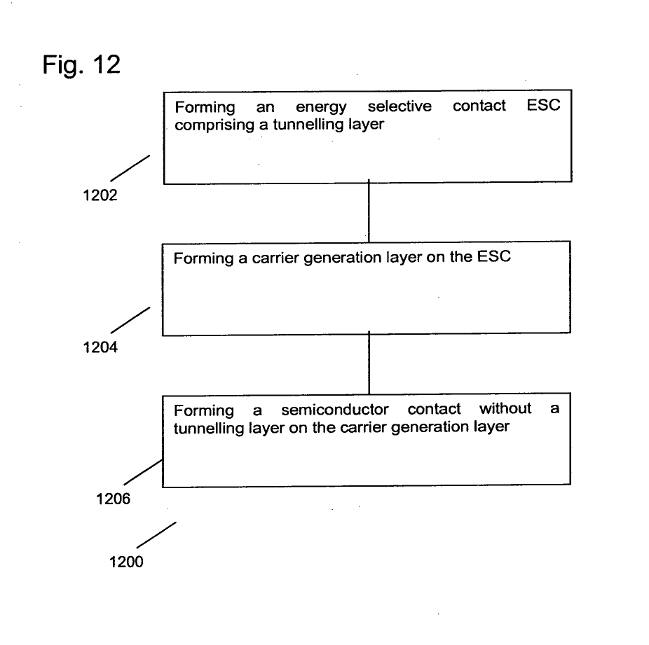

FIG. 12 shows a flowchart 1200 illustrating a method of fabricating a hot carrier energy conversion structure according to an example embodiment. At step 1202, an energy selective contact ESC comprising a tunnelling layer is formed. At step 1204, a carrier generation layer is formed on the ESC. At step 1206, a semiconductor contact without a tunnelling layer is formed on the carrier generation layer.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

1. A method of fabricating a hot carrier energy conversion structure, the method comprising:
forming an energy selective contact (ESC) comprising a tunnelling layer;
forming a carrier generation layer on the ESC; and
forming a semiconductor contact without a tunnelling layer on the carrier generation layer.

2. The method as claimed in claim 1, wherein the ESC comprises a negative ESC, and the semiconductor contact comprises a positive semiconductor contact,

3. The method as claimed in claim 1, further comprising the step of controlling a work function of the semiconductor contact for controlling a work function difference between the ESC and the semiconductor contact.

4. The method as claimed in claim 3, wherein the controlling the work function of the semiconductor contact comprises selecting a material of the semiconductor contact, an oxide of the semiconductor contact, or both.

5. The method as claimed in claim 1, wherein no high temperature annealing step is performed after the forming of the carrier generation layer.

6. The method as claimed in claim 1, wherein the tunnelling layer provides total energy filtering.

7. The method as claimed in claim 1, wherein the semiconductor contact is formed so that an energy level of a lower end of its conduction band is higher than the mean energy level of electrons or a peak energy level of an energy-density distribution of electrons generated in the carrier generation layer.

8. The method as claimed in claim 1, wherein an energy level of a lower end of a conduction band of the semiconductor contact is higher than an energy level of an upper end of an energy-density distribution of electrons generated in the carrier generation layer.

9. The method as claimed in claim 1, wherein an energy level of a conduction band of the ESC is substantially equal to a mean energy level of electrons or a peak energy level of an energy-density distribution of electrons generated in the carrier generation layer.

10. The method as claimed in claim 1, wherein an energy level of an upper end of a valence band of the ESC is lower than a means energy level of holes or a peak energy level of an energy-density distribution of holes generated in the carrier generation layer.

11. The method as claimed in claim 1, wherein an energy level of an upper end of a valence band of the ESC is lower than a lower end of an energy-density distribution of holes generated in the carrier generation layer,

12. The method as claimed in claim 1, wherein the quantum effect layer comprises an n-type semiconductor material buried in a barrier layer and an energy level of a conduction band of the electron transfer layer is chosen by controlling a dopant concentration of the n-type semiconductor material.

13. The method as claimed in claim 12, wherein the barrier layer comprises another n-type semiconductor material and an energy level of the barrier layer is chosen by controlling a dopant concentration of said other n-type semiconductor material.

14. The method as claimed in claim 1, wherein the semiconductor contact is formed so that an energy level of an upper end of its valence hand is higher than an upper end of the valence hand of the carrier generation layer.

15. The method as claimed in claim 1, wherein the quantum effect layer comprises one of a group consisting of a quantum well layer, quantum wires, and quantum dots.

16. A hot carrier energy conversion structure comprising:
an energy selective contact ESC comprising a tunnelling layer;
a carrier generation layer on the ESC; and
a semiconductor contact without a tunnelling layer on the carrier generation layer.

17. The structure as claimed in claim 16, wherein the ESC comprises a negative ESC, and the semiconductor contact comprises a positive semiconductor contact.

18. The structure as claimed in claim 16, wherein a work function of the semiconductor contact is controlled for controlling a work function difference between the ESC and the semiconductor contact.

19. The structure as claimed in claim 18, wherein the controlling the work function of the semiconductor contact comprises selecting a material of the semiconductor contact, an oxide of the semiconductor contact, or both.

20. The structure as claimed in claim 16, wherein the tunnelling layer provides total energy filtering.

21. The structure as claimed in claim 16, wherein the semiconductor contact has an energy level of a lower end of its conduction band higher than the mean energy level of electrons or a peak energy level of an energy-density distribution of electrons generated in the carrier generation layer.

22. The structure as claimed in claim 16, wherein an energy level of a lower end of a conduction band of the semiconductor contact is higher than an energy level of an upper end of an energy-density distribution of electrons generated in the carrier generation layer.

23. The structure as claimed in claim 16, wherein an energy level of a conduction band of the ESC is substantially equal to a mean energy level of electrons or a peak energy level of an energy-density distribution of electrons generated in the carrier generation layer.

24. The structure as claimed in claim 16, wherein an energy level of an upper end of a valence band of the ESC is lower than a means energy level of holes or a peak energy level of an energy-density distribution of holes generated in the carrier generation layer.

25. The structure as claimed in claim 16, wherein an energy level of an upper end of a valence band of the ESC is lower than a lower end of an energy-density distribution of holes generated in the carrier generation layer.

26. The structure as claimed in claim 16, wherein the quantum effect layer comprises an n-type semiconductor material buried in a barrier layer and an energy level of a conduction band of the electron transfer layer is chosen by controlling a dopant concentration of the n-type semiconductor material.

27. The structure as claimed in claim 26, wherein the barrier layer comprises another n-type semiconductor material and an energy level of the barrier layer is chosen by controlling a dopant concentration of said other n-type semiconductor material.

28. The structure as claimed in claim 16, wherein the semiconductor contact has an energy level of an upper end of its valence band higher than an upper end of the valence band of the carrier generation layer.

29. The structure as claimed in claim 16, wherein the quantum effect layer comprises one of a group consisting of a quantum well layer, quantum wires, and quantum dots.

30. The structure as claimed in claim 16, further comprising means for applying between the positive electrode and the negative electrode a voltage adjusted so as to maximize an output of the energy conversion device.

31. The structure as claimed in claim 30, wherein the means for applying the voltage is a load whose resistance value has been adjusted so as to maximize said output.

32. The method as claimed in claim 1, further comprising applying between the positive electrode and the negative electrode a voltage adjusted so as to maximize an output of the energy conversion device.

33. The method as claimed in claim 32, wherein the applying the voltage uses a load whose resistance value has been adjusted so as to maximize said output.
